(19) United States
(12) Patent Application Publication
(10) Pub. No.: US 2006/0176045 A1
(43) Pub. Date: Aug. 10, 2006

(54) Plasma reactor and method of determining abnormality in plasma reactor

(75) Inventors: Kenji Dosaka, Wako-shi (JP); Kazuo Ando, Wako-shi (JP); Hideyuki Fujishiro, Wako-shi (JP); Minoru Torii, Wako-shi (JP); Koji Kotani, Wako-shi (JP); Takeshi Yanobe, Yokohama-shi (JP)

Correspondence Address: ARENT FOX PLLC, 1050 CONNECTICUT AVENUE, N.W., SUITE 400, WASHINGTON, DC, 20036, US

(73) Assignee: Fujitsu Limited

(21) Appl. No.: 11/377,287

(22) Filed: Mar. 17, 2006

Related U.S. Application Data
(62) Division of application No. 09/852,664, filed on May 11, 2001.

(30) Foreign Application Priority Data
May 12, 2000 (JP) 2000-139488
May 12, 2000 (JP) 2000-139489

(51) Int. Cl. G01R 23/16

(52) U.S. Cl. 324/76.12

(57) ABSTRACT

A plasma reactor is provided which does not require a high power supply voltage and can form a plasma with a necessary and sufficient average current density over the whole region between a pair of electrodes to efficiently modify a gas flowing between the electrodes. The plasma reactor comprises first and second electrodes positioned to face each other, a dielectric material placed between the two electrodes and an electrical power supply for applying an alternating or pulsed current to the two electrodes and generating a plasma in the gas passing through the gap between the two electrodes to thereby modify the gas. By setting the average current density Ird of the plasma generated in the gap so that it satisfies the formula 10⁻⁴ A/cm²≦Ird≦10⁻¹ A/cm², a concentrated discharge and a barrier discharge are simultaneously generated, thus forming a plasma having a sufficient average current density Ird for the efficient modification of the gas over the whole region of the gap.

### CROSS-REFERENCE TO RELATED APPLICATIONS

This is a Division of Application No. 09/852,664 filed May 1, 2001. The disclosure of the prior application(s) is hereby incorporated by reference herein in its entirety.

### BACKGROUND OF THE INVENTION

1. Field of the Invention

The present invention relates to a plasma reactor comprising a pair of electrodes facing each other, a dielectric material placed between the pair of electrodes, and an electrical power source for applying an alternating current or a pulsed current to the pair of electrodes, wherein a plasma is generated in a gas flowing through the gap between the pair of electrodes to thereby modify the gas, and a method of determining an abnormality therein.

2 Description of the Prior Art

Catalysts have been used in the prior art for the removal of toxic gases (NOₓ, SOₓ, CO, etc.) in combustion exhaust gases, the removal of environmental pollutants (freons, halons, dioxins, etc.), the dehydrogenation of organic gases, the decomposition of CO₂ and the like, but the modification of a gas by means of a plasma reactor has only recently been receiving attention.

A plasma is a state in which an originally insulating gas becomes electrically conductive due to the application of a strong electrical field, and a gas in this plasma state comprises a mixture of positive and negative ions, electrons, excited neutral species, etc. and is in an activated state in which chemical reactions readily occur. It is therefore possible to directly react a target gas by means of a plasma reactor to modify it without involving oxidation/reduction as in conventional catalytic reactions. In order to effect a catalytic reaction, it is necessary to contact the gas with the catalyst supported on the surface of a support, and the reaction occurs only on the two dimensional catalyst surface. However, since reactions due to a plasma occur in a three dimensional space, the gas can be modified with high efficiency.

There are two types of plasma reactors which are known at present. In a first type of plasma reactor, an alternating or direct current is applied to a pair of electrodes facing each other to produce a discharge column similar to that of lightning (concentrated discharge). In a second type of plasma reactor, one or both of a pair of electrodes facing each other are covered with a dielectric material such as glass and an alternating or pulsed current is applied to the electrodes to form a large number of micro discharge columns (barrier discharge). The plasma formed by the barrier discharge is a ‘non-equilibrium plasma’ that has a significantly higher electron temperature than that of the gas or ions, and since the electron energy is as high as 1 eV to 10 eV, it is considered to be suitable for activating the gas to accelerate its reaction.

Japanese Patent Application Laid-open No. 6-106025 discloses an exhaust gas cleaning system for cleaning up the NO in an exhaust gas. This exhaust gas cleanup system removes NO by the combined use of an exhaust gas cleaning catalyst and a plasma reactor. Two types of plasma reactors are disclosed, one in which an alternating current is applied to a pair of electrodes to thereby generate a concentrated discharge similar to that of lightning and one in which an alternating current is applied to a pair of electrodes, at least one of the electrodes being covered with a dielectric material, to thereby generate a barrier discharge.

Since the first type of plasma reactor produces a concentrated discharge similar to that of lightning, although the energy potential of the plasma is high, a uniform plasma field cannot be formed over the whole region between the pair of electrodes due to the small discharge area, and there is therefore the problem that it is difficult to pass a gas effectively through the plasma field and modify it efficiently. On the other hand, although the second type of plasma reactor can form a uniform plasma field over the whole region between the pair of electrodes due to the barrier discharge, since the average current density at the discharge surface is as low as 10⁻⁶ A/cm² to 10⁻⁵ A/cm², its capacity is insufficient when treating a gas at a high concentration or at a high flow rate, and as a result it becomes necessary to increase the size of the plasma reactor causing the problem of increased electrical power consumption. Moreover, since a dielectric material is present between the electrodes, an applied voltage of 10 kVp or more is often required causing the problem of increased load on the power supply.

Furthermore, determining abnormality in a plasma reactor used for cleaning the exhaust gas from an automobile has been carried out in the art by detecting the composition of the exhaust gas by means of a gas sensor provided in the exhaust pipe on the downstream side of the plasma reactor and checking whether or not the plasma reactor is cleaning toxic components from the exhaust gas as normal.

However, with regard to the conventional method of determining abnormality, there are the problems that not only is the gas sensor the main cause of an increase in cost but also abnormality in the plasma reactor cannot be determined unless the engine is actually in operation and, since there is a time lag between the point when the exhaust gas passes through the plasma reactor and the point when it arrives at the gas sensor, abnormality in the plasma reactor cannot be determined in real time.

### SUMMARY OF THE INVENTION

The present invention has been carried out in view of the above-mentioned circumstances, and it is a first object of the present invention to provide a plasma reactor which does not require a high power supply voltage and can form a plasma with a necessary and sufficient average current density over the whole region between a pair of electrodes thereby efficiently modifying a gas.

Moreover, it is a second object of the present invention to provide a method of determining abnormality in a plasma reactor in real time without employing an expensive gas sensor and without actually passing a gas through the plasma reactor.

In order to achieve the first object, in accordance with a first characteristic of the present invention there is proposed a plasma reactor comprising a pair of electrodes facing each other, a dielectric material placed between the pair of electrodes and an electrical power supply for applying an alternating or pulsed current to the pair of electrodes, and generating a plasma in a gas passing through the gap between the pair of electrodes to thereby modify it, wherein the average current density Ird of the plasma so generated satisfies the formula below.
10⁻⁴ A/cm²≦Ird≦10⁻¹ A/cm²

In accordance with this arrangement, a concentrated discharge and a barrier discharge are simultaneously generated by setting the average current density Ird of the plasma lower than the average current density Ird of an ordinary concentrated discharge and higher than the average current density Ird of an ordinary barrier discharge. As a result, a plasma having an adequate average current density Ird sufficient for carrying out efficient modification of the gas can be generated over the whole region between the pair of electrodes. Moreover, since the upper limit of the average current density Ird is controlled, it is possible to prevent damage to the dielectric material due to an excessive average current density Ird and to prevent any increase in the load on the electrical power supply.

Furthermore, in order to achieve the first object, in accordance with a second characteristic of the present invention, there is proposed a plasma reactor comprising a pair of electrodes facing each other, a dielectric material placed between the pair of electrodes and an electrical power supply for applying an alternating or pulsed current to the pair of electrodes, and generating a plasma in a gas passing through the gap between the pair of electrodes to thereby modify it, wherein the formulae below are satisfied when the total size of the gap is d and the thickness of the dielectric material is t.
0.1 mm≦t≦2.0 mm
d+t≦5 mm
d/t≦5

In accordance with this arrangement, concentrated discharge and barrier discharge are simultaneously generated over the whole region between the pair of electrodes by setting the thickness t of the dielectric material, the sum of the total size d of the gap between the pair of electrodes and the thickness t of the dielectric material (i.e. the distance between the pair of electrodes), and the quotient of the total size d of the gap divided by the thickness t of the dielectric material in predetermined ranges, and as a result the gas can be modified with high efficiency.

In order to achieve the first object, in accordance with a third characteristic of the present invention, in addition to the first or second characteristic, there is proposed a plasma reactor wherein the dielectric material is not in contact with the electrodes.

In accordance with this arrangement, since the dielectric material is not in contact with the electrodes, the number of electrode surfaces and dielectric material surfaces can be increased thus modifying the gas yet more efficiently, the density of activated species in the plasma being high on the surfaces.

In order to achieve the first object, in accordance with a fourth characteristic of the present invention, in addition to the third characteristic, there is proposed a plasma reactor wherein the amount a that the center of the dielectric material in the width direction, is offset from the midpoint of the distance between the pair of electrodes, satisfies the formula below.
0≦a≦0.5×(d/2)

In accordance with this arrangement, by setting the amount a that the center of the dielectric material in the width direction is offset from the midpoint of the distance between the pair of electrodes in a predetermined range, it is possible to ensure that the gap between the dielectric material and one of the electrodes is larger than a minimum size, and to prevent the modification efficiency from being degraded due to it being difficult for the gas to pass through the gap.

In the case where the dielectric material is in contact with one of the electrodes, the number of gaps is one (1) and the size of the gap equals the total size d of the gap. In the case where the dielectric material is not in contact with the electrodes, the number of gaps is two (2) and the total of the size of the two gaps equals the total size d of the gap.

In order to achieve the second object, in accordance with a fifth characteristic of the present invention, there is proposed a method of determining abnormality in a plasma reactor, the plasma reactor modifying a gas by applying an alternating current to electrodes facing each other, thus generating a plasma in the gas passing through the gap between the two electrodes, wherein the determination of abnormality is based on a change in the waveform of the voltage or current of the alternating current.

In accordance with this arrangement, since the determination of abnormality is based on a change in the waveform of the voltage or current of the alternating current that is applied to the electrodes of the plasma reactor, abnormality can be determined without actually passing a gas through the plasma reactor. Furthermore, no gas sensor for detecting the gas composition is needed; not only can the cost be reduced but also there is no time lag between the gas passing through the plasma reactor and reaching the gas sensor, and as a result abnormality can be determined in real time.

Moreover, in order to achieve the second object, in accordance with a sixth characteristic of the present invention, in addition to the fifth characteristic, there is proposed a method of determining abnormality in a plasma reactor wherein abnormality is determined if a spike-shaped abnormal waveform is detected when the waveform of the voltage or current of the alternating current is filtered by means of a high-pass filter.

In accordance with this arrangement, since abnormality is determined if a spike-shaped abnormal waveform is detected in the waveform of the alternating current applied to the plasma reactor, abnormality due to deterioration of the plasma reactor can be determined accurately.

Furthermore, in order to achieve the second object, in accordance with a seventh characteristic of the present invention, in addition to the fifth characteristic, there is proposed a method of determining abnormality in a plasma reactor wherein abnormality is determined if a spike-shaped abnormal waveform is detected when the waveform of the voltage or current of the alternating current is compared with a reference waveform.

In accordance with this arrangement, since abnormality is determined if a spike-shaped abnormal waveform is detected in the waveform of the alternating current applied to the plasma reactor, abnormality due to deterioration of the plasma reactor can be determined accurately.

The above-mentioned objectives, other objectives, characteristics and advantages of the present invention will become apparent from an explanation of preferred embodiments which will be described in detail below by reference to the attached drawings.

### BRIEF DESCRIPTION OF THE DRAWINGS

FIGS. 1 to 3 illustrate a first embodiment of the present invention.

FIG. 1 is a diagram showing a plasma reactor wherein a dielectric material is in contact with an electrode.

FIG. 2 is a diagram showing a gas modification system employing a plasma reactor.

FIG. 3 is a graph showing the relationship between the average current density and the NO concentration in the first embodiment.

FIG. 4 is a graph showing the relationship between the average current density and the percentage CO₂ conversion in a second embodiment.

FIGS. 5 and 6 illustrate a third embodiment of the present invention.

FIG. 5 is a graph showing the relationship between the electrode distance and the average current density in the third embodiment.

FIG. 6 is a diagram showing a plasma reactor wherein the dielectric material is not in contact with the electrodes.

FIG. 7 is a graph showing the relationship between the gas flow rate and the percentage removal of NO in a fourth embodiment.

FIG. 8 is a graph showing the relationship between the offset and the percentage CO₂ conversion in a fifth embodiment.

FIGS. 9 to 12 illustrate a sixth embodiment of the present invention.

FIG. 9 is a diagram showing the overall arrangement of a system for determining abnormality in a plasma reactor used for cleaning up the exhaust gas of an automobile.

FIG. 10 is a schematic view for explaining the structure of the plasma reactor.

FIG. 11 is a graph showing the voltage waveform when abnormality occurs.

FIG. 12 is a circuit diagram showing a circuit for determining abnormality in a plasma reactor.

FIG. 13 is a circuit diagram showing a circuit for determining abnormality in a plasma reactor related to a seventh embodiment.

### DESCRIPTION OF PREFERRED EMBODIMENTS

Embodiments of the present invention are explained below by reference to the drawings.

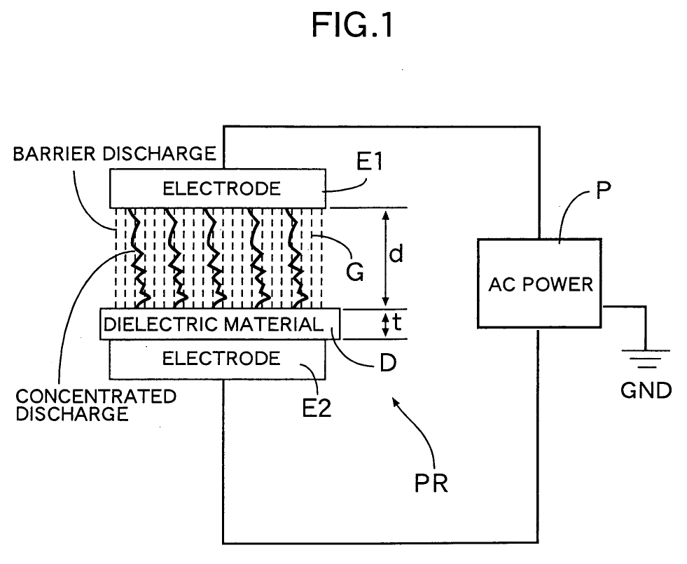

A plasma reactor PR shown in FIG. 1 comprises first and second electrodes E1 and E2, made of metal, placed in parallel so as to face each other, a dielectric material D having a high relative dielectric constant, the dielectric material D being placed so as to have one surface in contact with the surface of the second electrode E2 facing the first electrode E1, and an electrical power supply P for outputting an alternating or pulsed current having a waveform such as a sine wave, a square wave, a triangle wave or a combined wave thereof, the first electrode El and the second electrode E2 being connected to a pair of terminals of the electrical power supply P. The size of the gap G between the first and second electrodes E1 and E2, that is to say, the gap G between the surface of the dielectric material D on the side opposite to that in contact with the second electrode E2 and the surface of the first electrode E1 facing the surface of the dielectric material D, is set at d, and the thickness of the dielectric material D is set at t. A gas passing through the gap G between the first electrode E1 and the dielectric material D is activated to be in a plasma state by the concentrated discharge and the barrier discharge simultaneously generated within the gap, and as a result the chemical reactions of the gas are accelerated thus modifying the gas.

In this case, the average current density Ird of the plasma is set so as to be in the range below.
10⁻⁴ A/cm²≦Ird≦10⁻¹ A/cm²

The average current density Ird referred to here is the value obtained by dividing the effective current Ims flowing in the plasma reactor PR by the discharge area Sd where the discharge actually occurs (Ird=Ird/Sd). The following formula is also satisfied when the thickness of the dielectric material is t and the size of the gap G is d.
0.1 mm≦t≦2.0 mm
d+t≦5 mm
d/t≦5

By so doing, plasma due to the concentrated discharge and plasma due to the barrier discharge can be generated simultaneously over the whole region in the gap G between the first electrode E1 and the dielectric material D, and the gas passing through the gap can be modified efficiently by a high energy potential plasma due to the concentrated discharge and a uniform plasma due to the barrier discharge.

The level of the above-mentioned average current density Ird exceeds the level of the average current density Ird of a normal barrier discharge; a first reason why such a high average current density Ird is realised is attributable to the combination of a plasma due to concentrated discharge and a plasma due to barrier discharge, and a second reason is attributable to the setting of the thickness t of the dielectric material D and the size d of the gap G as described above. That is to say, since the thickness t of the dielectric material D and the size d of the gap G are set to be comparatively small, the impedance between the first and second electrodes E1 and E2 decreases making the current flow easily during discharge. At the same time, since the discharge start voltage (breakdown voltage) can be lowered, the input voltage, which has been required to be at least 10 kVp in the prior art, can be reduced to 8 kVp or below thus easing the load on the electrical power supply P, and the reduction in the size of the power source P makes it easier to install the plasma reactor in a vehicle, etc. where space efficiency is required.

A first embodiment of the present invention is explained below by reference to FIGS. 1 to 3 and Tables 1 and 2.

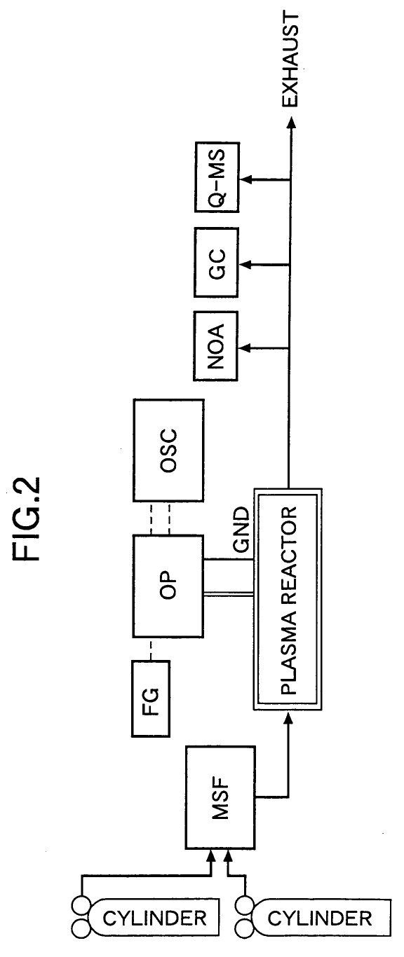

The first embodiment verifies the ability of the plasma reactor PR shown in FIG. 1 and a system shown in FIG. 2 to remove NO. As shown in FIG. 2, pure N₂, pure CO₂, pure O₂, and a gaseous mixture comprising pure N₂ and 512 ppm of NO are fed out of cylinders, mixed by means of a mass flow controller MSF, and then supplied to the plasma reactor PR. The plasma reactor PR is operated by means of a high frequency high voltage operational amplifier OP. Voltage, waveform and frequency signals are input from a function generator FG to the operational amplifier OP and the operational amplifier OP applies an alternating current having a predetermined voltage and current to the first and second electrodes E1 and E2 of the plasma reactor PR. The voltage and current of the alternating current applied to the plasma reactor PR are monitored by a digital oscilloscope OSC. The modified gas that has passed through the plasma reactor PR is qualitatively and quantitatively analysed by means of a quadrupole mass filter Q-MS and a photoluminescent NOₓ analyser NOA or a gas chromatograph GC, and then discharged.

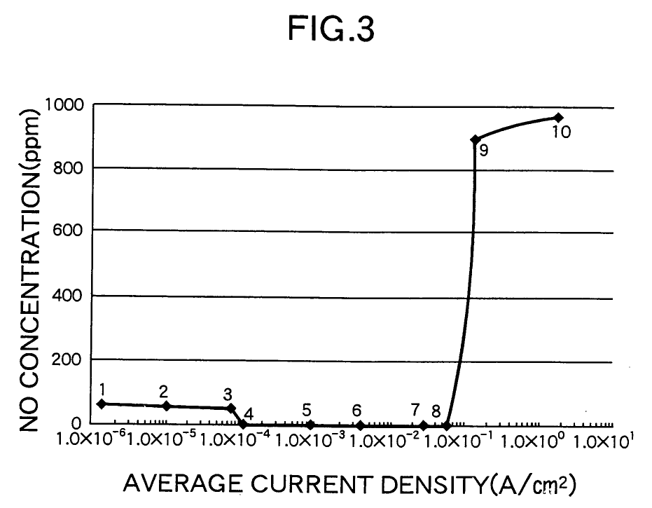

A gas having a composition of 10 vol % of CO₂, 10 vol % of O₂, and 130 ppm of NO with the remainder being N₂ is supplied to the plasma reactor PR, and an alternating voltage having a square waveform is applied to the first and second electrodes E1 and E2. The dielectric material D covering the second electrode E2 is made of Al₂O₃ (alumina), and the area of each of the first and second electrodes E1 and E2 is 2 cm² (20 mm×10 mm). The concentration of NO present in the gas that has passed through the plasma reactor PR is quantified by means of the photoluminescent NOₓ analyser NOA, and the ability to remove NO is thus evaluated. The test conditions and test results are given in Tables 1 and 2 and FIG. 3.

TABLE 1
Embodiment 1
Test Conditions

| | | Thickness | | | Input | Fre- |
|---|---|---|---|---|---|---|
| | | of dielectric | Gap; | Discharge | voltage; | quency; |
| | Dielectric | material; t | d | area; S | Vin | f |
| No. | material | (mm) | (mm) | (cm²) | (kVp) | (kHz) |
| 1 | Al₂O₃ | 2.5 | 7.0 | 2.0 | 15.0 | 20 |
| 2 | ↑ | 2.5 | 5.0 | 2.0 | 14.0 | 20 |
| 3 | ↑ | 2.2 | 4.0 | 2.0 | 14.0 | 25 |
| 4 | ↑ | 1.5 | 2.0 | 2.0 | 6.0 | 30 |
| 5 | ↑ | 1.0 | 1.0 | 2.0 | 4.5 | 20 |
| 6 | ↑ | 0.5 | 1.0 | 2.0 | 3.0 | 20 |
| 7 | ↑ | 0.5 | 0.5 | 2.0 | 2.6 | 10 |
| 8 | ↑ | 0.2 | 0.5 | 2.0 | 2.0 | 10 |
| 9 | — | — | 0.5 | 2.8 × 10⁻³ | 1.5 | 5 |
| 10 | — | — | 0.5 | 2.8 × 10⁻³ | 2.0 | 5 |

TABLE 2
Embodiment 1
Test Results

| | | Average | | |
|---|---|---|---|---|
| | Effective current; | current | NO | |
| | lrms | density; lrd | concentration | Discharge |
| No. | (A) | (A/cm²) | (ppm) | state |
| 1 | 2.8E−06 | 1.4 × 10⁻⁶ | 56 | Micro |
| | | | | discharge |
| | | | | columns |
| 2 | 2.2E−05 | 1.1 × 10⁻⁵ | 54 | ↑ |
| 3 | 1.6E−04 | 8.0 × 10⁻⁵ | 48 | ↑ |
| 4 | 2.4E−04 | 1.2 × 10⁻⁴ | 0 | Uniform + |
| | | | | discharge |
| | | | | columns |
| 5 | 1.8E−03 | 9.0 × 10⁻⁴ | 0 | ↑ |
| 6 | 8.0E−03 | 4.0 × 10⁻³ | 0 | ↑ |
| 7 | 6.0E−02 | 3.0 × 10⁻² | 0 | ↑ |
| 8 | 1.2E−01 | 6.0 × 10⁻² | 0 | ↑ |
| 9 | 4.0E−04 | 4.0 × 10⁻¹ | 892 | Discharge |
| | | | | columns |
| | | | | (lightning-like) |
| 10 | 5.0E−03 | 1.8 × 10⁰ | 960 | ↑ |

In Nos. 1 to 8, a barrier discharge (micro discharge columns or medium size discharge columns) is generated, but in Nos. 9 and 10 a concentrated discharge (lightning-like discharge columns) is generated without a barrier discharge. The reason why no dielectric material D is used in Nos. 9 and 10 is that dielectric breakdown of the dielectric material D easily occurs when the average current density Ird is increased to 0.1 A/cm² or above. When dielectric breakdown of the dielectric material D occurs, the discharge becomes similar to a concentrated discharge generated between the first and second electrodes E1 and E2. In this case the discharge area Sd is not the 2 cm² area of the surface of the first and second electrodes E1 and E2 as is the case with a barrier discharge, but rather the discharge area Sd corresponds to the cross section of the concentrated discharge that can be determined from the discharge marks remaining on the first and second electrodes E1 and E2 (e.g. Sd=2.8×10⁻³ cm²; φ0.6 mm).

In Nos. 1 to 3 where the average current density Ird is less than 10⁻⁴ A/cm2, although a large number of micro discharge columns are generated due to the barrier discharge, since the energy level of the plasma is low, an adequate ability to remove NO cannot be obtained. When the reactor is arranged so that t+d is more than 5 mm and d/t is more than 5, a fairly high input voltage is required in order to achieve an average current density Ird of 10⁻⁴ A/cm² or above, and this is difficult to realise since dielectric breakdown of the dielectric material D occurs and the electrical power supply P is overloaded.

On the other hand, in Nos. 4 to 8 where the thickness t of the dielectric material D and the size d of the gap G are small, a uniform barrier discharge similar to low voltage glow discharge and a plurality of medium size concentrated discharges are mixed (hereinafter, termed complex barrier discharge) thus increasing the average current density Ird to 10⁻⁴ A/cm² or higher. When this complex barrier discharge is in progress, since a uniform plasma field is generated in the gap G, the gas molecules that pass through the gap are excited to a certain degree and, furthermore, ionisation and decomposition of the gas molecules are easily accelerated by the concentrated discharge, and chemical reactions take place. In the complex barrier discharge, since a barrier discharge and a concentrated discharge are mixed, the average current density Ird can be increased without disturbing the discharge state, even if the input voltage is increased to increase the circuit current.

As in Nos. 9 and 10, when the average current density Ird is higher than 10⁻¹ A/cm², a plurality of concentrated discharges in the complex barrier discharge aggregate into one large concentrated discharge, and there is a possibility of dielectric breakdown of the dielectric material D occurring. It is surmised that when the charge density on the dielectric material D increases, nonuniformities in the charge distribution that have been moderated up to that point, cannot be moderated any more, and the nonuniformities in the charge distribution are further emphasised. As a result, the discharge so generated is a lightning-like concentrated discharge, which is the same as the concentrated discharge generated between exposed electrodes E1 and E2 (although there is no dielectric material D provided in the embodiment, the result is the same even if a dielectric material D is provided). In this case the discharge area Sd corresponds to about 2.8×10⁻³ cm² (corresponding to φ=0.6 mm) as mentioned above, the energy density of the plasma is excessive, and excitation of N₂ and O₂ in the gas is accelerated so forming NO rather than removing NO.

As hereinbefore described, by setting the average current density Ird to satisfy the formula 10⁻⁴ A/cm²≦Ird≦10⁻¹ A/cm² as in Nos. 4 to 8, it is possible for the ability to remove NO to be exhibited to the largest extent.

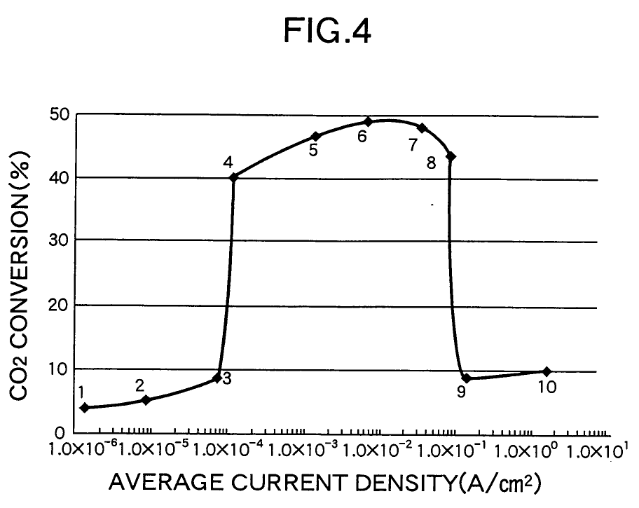

Next, the second embodiment is explained by reference to Tables 3 and 4 and FIG. 4.

The second embodiment verifies the ability of the plasma reactor PR shown in FIG. 1 and the system shown in FIG. 2 to decompose CO₂ into CO and O₂. The composition of the gas supplied to the plasma reactor PR is adjusted to contain 10 vol % of CO₂ and 90 vol % of N₂ by means of the mass flow controller MSF using pure N₂ and pure CO₂. The dielectric material D is made of ZrO₂, and the amount of CO formed by the plasma reaction is quantified by the gas chromatograph GC to determine the conversion of CO₂. The test conditions and the test results are given Tables 3 and 4 and FIG. 4.

TABLE 3
Embodiment 2
Test Conditions

| | | Thickness | | | | |
|---|---|---|---|---|---|---|
| | | of | | | Input | |
| | | dielectric | Gap; | Discharge | voltage; | Frequency; |
| | Dielectric | material; t | d | area; S | Vin | f |
| No. | material | (mm) | (mm) | (cm²) | (kVp) | (kHz) |
| 1 | ZrO₂ | 2.5 | 7.0 | 2.0 | 13.0 | 15 |
| 2 | ↑ | 2.5 | 5.0 | 2.0 | 12.0 | 15 |
| 3 | ↑ | 2.2 | 4.0 | 2.0 | 11.0 | 17 |
| 4 | ↑ | 1.5 | 2.0 | 2.0 | 5.0 | 50 |
| 5 | ↑ | 1.0 | 1.0 | 2.0 | 3.4 | 47 |
| 6 | ↑ | 0.5 | 1.0 | 2.0 | 2.4 | 45 |
| 7 | ↑ | 0.5 | 0.5 | 2.0 | 2.0 | 45 |
| 8 | ↑ | 0.2 | 0.5 | 2.0 | 1.8 | 43 |
| 9 | — | — | 0.5 | 2.8 × 10⁻³ | 1.5 | 5 |
| 10 | — | — | 0.5 | 2.8 × 10⁻³ | 2.0 | 5 |

TABLE 4
Embodiment 2
Test Results

| | | Average | | |
|---|---|---|---|---|
| | Effective current; | current | | |
| | lrms | density; lrd | CO₂ | Discharge |
| No. | (A) | (A/cm²) | conversion (%) | state |
| 1 | 3.0 × 10⁻⁶ | 1.5 × 10⁻⁶ | 3.8 | Micro |
| | | | | discharge |
| | | | | columns |
| 2 | 1.8 × 10⁻⁵ | 9.0 × 10⁻⁶ | 5.1 | ↑ |
| 3 | 1.6 × 10⁻⁴ | 8.0 × 10⁻⁵ | 8.2 | ↑ |
| 4 | 2.4 × 10⁻⁴ | 1.3 × 10⁻⁴ | 40.5 | Uniform + |
| | | | | discharge |
| | | | | columns |
| 5 | 3.0 × 10⁻³ | 1.5 × 10⁻³ | 46.7 | ↑ |
| 6 | 1.5 × 10⁻² | 7.5 × 10⁻³ | 48.9 | ↑ |
| 7 | 8.0 × 10⁻² | 4.0 × 10⁻² | 48.2 | ↑ |
| 8 | 1.8 × 10⁻¹ | 9.0 × 10⁻² | 43.6 | ↑ |
| 9 | 4.0 × 10⁻⁴ | 1.4 × 10⁻¹ | 8.7 | Discharge |
| | | | | columns |
| | | | | (lightning-like) |
| 10 | 5.0 × 10⁻³ | 1.8 × 10⁰ | 10.1 | ↑ |

In Nos. 1 to 3 the average current density Ird is less than 10⁻⁴ A/cm²; although a large number of micro discharge columns due to a barrier discharge, are generated, and adequate ability to decompose CO₂ cannot be obtained due to the low energy level of the plasma, and the conversion remains low.

On the other hand, in the case of a complex barrier discharge as in Nos. 4 to 8 in which a uniform barrier discharge and a plurality of medium level concentrated discharges are mixed, the average current density Ird is increased to 10⁻⁴ A/cm² or above thus forming a uniform plasma field in the gap G, the decomposition of CO₂ is accelerated by the excitation of the gas molecules due to the barrier discharge and ionisation and decomposition of the gas molecules due to the concentrated discharge thus achieving a high conversion.

When the average current density Ird is higher than 10⁻¹ A/cm² as in Nos. 9 and 10, only one lightning-like concentrated discharge is generated, the probability of contact between the gas and the plasma is lowered, and the percentage decomposition of CO₂ is degraded in spite of the plasma having a high energy level.

As hereinbefore described, by setting the average current density Ird in the range 10⁻⁴ A/cm²≦Ird≦10⁻¹ A/cm², the ability to decompose CO₂ can be maximised.

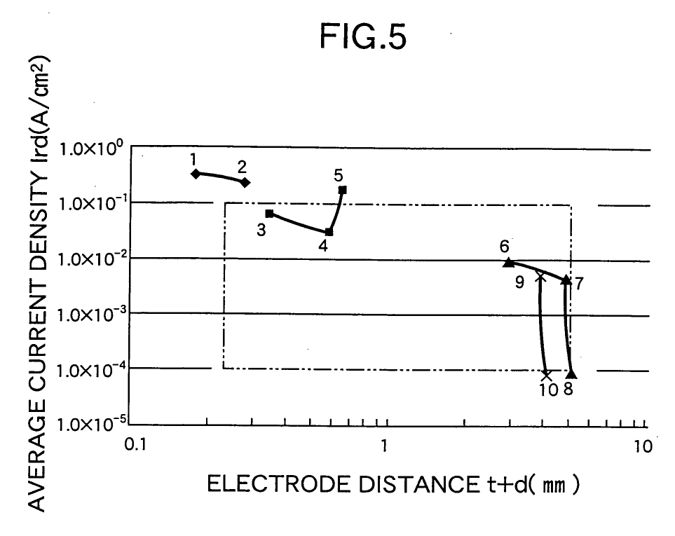

The third embodiment is explained below by reference to Tables 5 and 6 and FIG. 5.

TABLE 5
Test Conditions
Embodiment 3

| | | Thickness | | | | | | |
|---|---|---|---|---|---|---|---|---|
| | | of | | | | Discharge | Input | |
| | | dielectric | Gap; | | | area; | voltage; | Frequency; |
| | Dielectric | material; t | d | d/t | d + t | S | Vin | f |
| No. | material | (mm) | (mm) | — | (mm) | (cm²) | (kVp) | (kHz) |
| 1 | ZrO₂ | 0.08 | 0.1 | 1.25 | 0.18 | 2.8 × 10⁻³ | 1.4 | 20 |
| 2 | ↑ | 0.08 | 0.2 | 2.5 | 0.28 | 2.8 × 10⁻³ | 1.5 | 20 |
| 3 | ↑ | 0.1 | 0.25 | 2.5 | 0.35 | 2.0 | 1.5 | 30 |
| 4 | ↑ | 0.1 | 0.5 | 5 | 0.6 | 2.0 | 1.8 | 30 |
| 5 | ↑ | 0.1 | 0.55 | 5.5 | 0.65 | 2.8 × 10⁻³ | 2.0 | 30 |
| 6 | ↑ | 1 | 2 | 2 | 3 | 2.0 | 5.2 | 40 |
| 7 | ↑ | 1 | 4 | 4 | 5 | 2.0 | 7.8 | 40 |
| 8 | ↑ | 1 | 4.2 | 4.2 | 5.2 | 2.0 | 8.4 | 40 |
| 9 | ↑ | 2 | 2 | 1 | 4 | 2.0 | 3.2 | 50 |
| 10 | ↑ | 2.2 | 2 | 0.91 | 4.2 | 2.0 | 6.5 | 50 |

TABLE 6
Embodiment 3
Test Results

| | | Average | | |
|---|---|---|---|---|
| | Effective current; | current | CO₂ | |
| | lrms | density; lrd | conversion | |
| No. | (A) | (A/cm²) | (%) | Discharge state |
| 1 | 9.2 × 10⁻⁴ | 3.3 × 10⁻¹ | 9.5 | Discharge |
| | | | | columns |
| | | | | (lightning-like) |
| 2 | 6.4 × 10⁻⁴ | 2.3 × 10⁻¹ | 8.6 | Discharge |
| | | | | columns |
| | | | | (lightning-like) |
| 3 | 1.3 × 10⁻¹ | 6.5 × 10⁻² | 45.3 | Uniform + |
| | | | | discharge |
| | | | | columns |
| 4 | 6.3 × 10⁻² | 3.2 × 10⁻² | 47.9 | Uniform + |
| | | | | discharge |
| | | | | columns |
| 5 | 4.8 × 10⁻⁴ | 1.7 × 10⁻¹ | 8.8 | Discharge |
| | | | | columns |
| | | | | (lightning-like) |
| 6 | 1.7 × 10⁻² | 8.5 × 10⁻³ | 47.7 | Uniform + |
| | | | | discharge |
| | | | | columns |
| 7 | 8.4 × 10⁻³ | 4.2 × 10⁻³ | 46.8 | Uniform + |
| | | | | discharge |
| | | | | columns |
| 8 | 1.8 × 10⁻⁴ | 9.0 × 10⁻⁵ | 8.6 | Micro discharge |
| | | | | columns |
| 9 | 9.6 × 10⁻³ | 4.8 × 10⁻³ | 46.4 | Uniform + |
| | | | | discharge |
| | | | | columns |
| 10 | 1.6 × 10⁻⁴ | 8.0 × 10⁻⁵ | 8.2 | Micro discharge |
| | | | | columns |

The third embodiment verifies the influence of the thickness t of the dielectric material D and the size d of the gap G on the ability to decompose CO₂ using a gas having the same composition as in the embodiment 2. When the thickness t of the dielectric material D is less than 0.1 mm as in Nos. 1 and 2, since dielectric breakdown of the dielectric material D occurs thus generating one large concentrated discharge, the probability of contact between the gas and the plasma decreases thus degrading the percentage decomposition of CO₂. The reason why dielectric breakdown occurs is that the dielectric material D is too thin to withstand the strength of the electric field formed between the first and second electrodes E1 and E2. In this case, the average current density Ird is at least 0.1 A/cm², but the percentage decomposition of CO₂ is degraded.

When the thickness t of the dielectric material D is 0.1 mm as in Nos. 3 to 5, under conditions where the ratio d/t of the size d of the gap G to the thickness t of the dielectric material D is 5 or less, a complex barrier discharge is generated, thus enhancing the percentage decomposition of CO₂ (see Nos. 3 and 4). However, when the ratio d/t exceeds 5, dielectric breakdown of the dielectric material D occurs, thus generating one large concentrated discharge and thus greatly degrading the percentage decomposition of CO₂ (see No. 5). The reason is that the increased size d of the gap G requires a high input voltage, and the increase in the size d of the gap G relative to the thickness t of the dielectric material D, makes the electrical field between the first and second electrodes E1 and E2 applied to the dielectric material D much larger, thus effecting the breakdown of the dielectric.

When the thickness t of the dielectric material D is 1 mm as in Nos. 6 to 8, if the sum d+t of the size d of the gap G and the thickness t of the dielectric material D (i.e., the distance between the first and second electrodes E1 and E2) is 5 mm or below, a complex barrier discharge is generated (see Nos. 6 and 7), but if the distance d+t between the first and second electrodes E1 and E2 exceeds 5 mm, a simple barrier discharge is generated thus greatly degrading the percentage decomposition of CO₂ (see No. 8). It is surmised that when the distance d+t between the first and second electrodes E1 and E2 increases, the resistance element of the plasma increases and it becomes difficult for current to flow.

When varying the thickness t of the dielectric material D while fixing the size d of the gap G at 2 mm as in Nos. 6, 9 and 10, if the thickness t of the dielectric material D is 2 mm or less, a complex barrier discharge is generated (see Nos. 6 and 9), but if the thickness t of the dielectric material D exceeds 2 mm, it becomes a simple barrier discharge (see No. 10). It is also surmised that the resistance element increases due to thickening of the dielectric material D and it becomes difficult for current to flow.

In the region enclosed by the rectangular broken line in FIG. 5 including Nos. 3, 4, 6, 7 and 9 in which the distance d+t between the first and second electrodes E1 and E2 is 5 mm or less and the average current density Ird is between 10⁻⁴ A/cm² and 10⁻¹ A/cm², the percentage decomposition of CO₂ is maintained at a high level, but in the region outside the rectangle including Nos. 1, 2, 5, 8 and 10 the percentage decomposition of CO₂ is degraded.

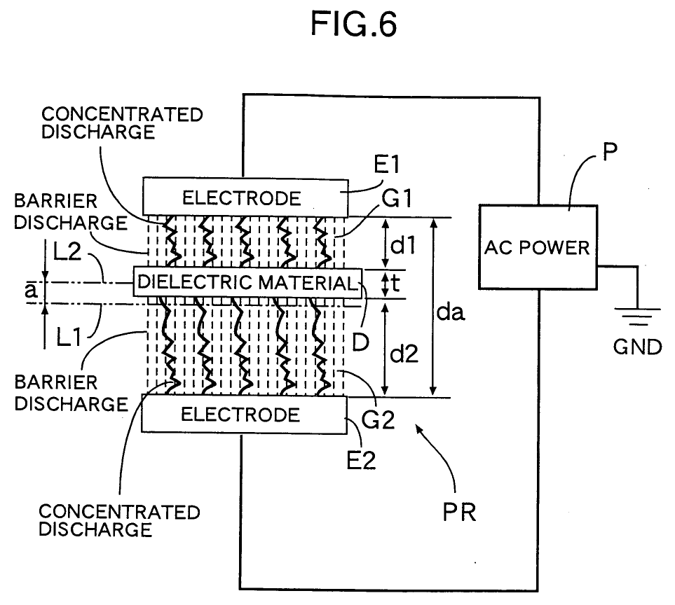

The plasma reactor PR shown in FIG. 1, in which the dielectric material D is in contact with the second electrode E2, comprises a single gap G, but in a plasma reactor PR shown in FIG. 6 neither of the first or the second electrodes E1 and E2 is in contact With the dielectric material D, a first gap G1 is formed between the first electrode E1 and the dielectric material D and a second gap G2 is formed between the second electrode E2 and the dielectric material D. The central line L2 of the dielectric material D in its thickness direction is offset by a distance a from the central line L1 between the first and second electrodes E1 and E2. The sizes of the first gap G1 and the second gap G2 are d1 and d2 respectively, and the total d of the sizes of the first gap G1 and the second gap G2 is d1+d2. When the thickness of the dielectric material D is t, the distance da between the first and second electrodes E1 and E2 is given by da=d1+d2+t=d+t.

Since the first gap G1 and the second gap G2 are formed on either side of the dielectric material D by placing the dielectric material D so as not to be in contact with the first and second electrodes E1 and E2, the efficiency of modifying the gas that passes through the gaps can be enhanced. It is surmised that the reason is that the active species in the plasma are localised on the surfaces of the electrodes E1 and E2 and the dielectric material D with which the gas is in contact, and placing the dielectric material D so as not to be in contact with the electrodes E1 and E2 increases the number of surfaces of the electrodes E1 and E2 and the dielectric material D that are in contact with the gas twice as many as in the plasma reactor shown in FIG. 1, thus accelerating the modification of the gas.

The performance of the plasma reactor PR shown in FIG. 6 is influenced also by the offset a of the dielectric material D. For example, if the dielectric material D is offset excessively towards the first electrode E1, since the size d1 of the first gap G1 between the dielectric material D and the first electrode E1 decreases, the gas cannot pass smoothly through the first gap G1, thus degrading the modification efficiency. Similarly, if the dielectric material D is offset excessively towards the second electrode E2, since the size d2 of the second gap G2 between the dielectric material D and the second electrode E2 decreases, the gas cannot pass smoothly through the second gap G2 thus degrading the modification efficiency.

It can be understood from the above results that there is a desirable upper limit value to the offset a of the dielectric material D, and the particular value for the upper limit is 0.5×(d/2). That is to say, when the offset a of the dielectric material D is 0, the sizes d1 and d2 of the first and second gaps G1 and G2 on either side of the dielectric material D are both d/2. The value obtained by multiplying the value d/2 by 0.5 is the upper limit value for the offset a. In other words, half of the maximum offset a that can be physically realised, namely, half of the offset a when the dielectric material D is in contact with either the first electrode E1 or the second electrode E2 corresponds to the upper limit value 0.5×d/2.

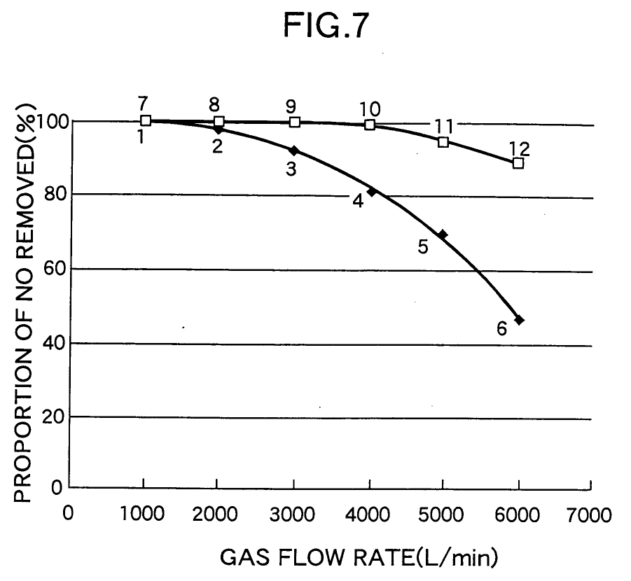

Next, the fourth embodiment is explained by reference to Tables 7 and 8 and FIG. 7.

The fourth embodiment which corresponds to the first embodiment verifies the ability of the plasma reactor PR shown in FIG. 6 when applied to the system shown in FIG. 2, to remove the NO present in the same gas as in the first embodiment. The test conditions are given in Table 7 and the test results are given in Table 8 and FIG. 7.

TABLE 7
Embodiment 4
Test Conditions

| | | Thickness | | | | | | |
|---|---|---|---|---|---|---|---|---|
| | | of | Electrode | | | | Input | Flow |
| | | dielectric | distance; | Offset; | | Frequen- | voltage; | rate; |
| | Dielectric | material; t | d | a | | cy; f | Vin | Q |
| No. | material | (mm) | (mm) | (mm) | d/t | (kHz) | (kVp) | (mL/min) |
| 1 | Al₂O₃ | 0.5 | 1 | 0.25 | 1 | 10 | 2.6 | 1000 |
| 2 | ↑ | ↑ | ↑ | ↑ | ↑ | ↑ | ↑ | 2000 |
| 3 | ↑ | ↑ | ↑ | ↑ | ↑ | ↑ | ↑ | 3000 |
| 4 | ↑ | ↑ | ↑ | ↑ | ↑ | ↑ | ↑ | 4000 |
| 5 | ↑ | ↑ | ↑ | ↑ | ↑ | ↑ | ↑ | 5000 |
| 6 | ↑ | ↑ | ↑ | ↑ | ↑ | ↑ | ↑ | 6000 |
| 7 | ↑ | ↑ | ↑ | 0 | ↑ | ↑ | 3.1 | 1000 |
| 8 | ↑ | ↑ | ↑ | ↑ | ↑ | ↑ | ↑ | 2000 |
| 9 | ↑ | ↑ | ↑ | ↑ | ↑ | ↑ | ↑ | 3000 |
| 10 | ↑ | ↑ | ↑ | ↑ | ↑ | ↑ | ↑ | 4000 |
| 11 | ↑ | ↑ | ↑ | ↑ | ↑ | ↑ | ↑ | 5000 |
| 12 | ↑ | ↑ | ↑ | ↑ | ↑ | ↑ | ↑ | 6000 |

TABLE 8
Embodiment 4
Test Results

| | | Average | | |
|---|---|---|---|---|
| | Effective | current | NO | Proportion of |
| | current; lrms | density; lrd | concentration | NO removed |
| No. | (A) | (A/cm²) | (ppm) | (%) |
| 1 | 5.90 × 10⁻² | 2.95 × 10⁻² | 0 | 100.0 |
| 2 | 5.90 × 10⁻² | 2.95 × 10⁻² | 3 | 97.7 |
| 3 | 5.90 × 10⁻² | 2.95 × 10⁻² | 10 | 92.3 |
| 4 | 5.90 × 10⁻² | 2.95 × 10⁻² | 25 | 80.8 |
| 5 | 5.90 × 10⁻² | 2.95 × 10⁻² | 40 | 69.2 |
| 6 | 5.90 × 10⁻² | 2.95 × 10⁻² | 70 | 46.2 |
| 7 | 6.30 × 10⁻² | 3.15 × 10⁻² | 0 | 100.0 |
| 8 | 6.30 × 10⁻² | 3.15 × 10⁻² | 0 | 100.0 |
| 9 | 6.30 × 10⁻² | 3.15 × 10⁻² | 0 | 100.0 |
| 10 | 6.30 × 10⁻² | 3.15 × 10⁻² | 1 | 99.2 |
| 11 | 6.30 × 10⁻² | 3.15 × 10⁻² | 8 | 93.8 |
| 12 | 6.30 × 10⁻² | 3.15 × 10⁻² | 15 | 88.5 |

Nos. 1 to 6 correspond to the case in which the dielectric material D is in contact with one of the first and second electrodes E1 and E2 (offset a=d/2), and Nos. 7 to 12 correspond to the case in which the dielectric material D is positioned in the center between the first and second electrodes E1 and E2 (offset a=0). As is clear from FIG. 7, when the flow rate of the gas increases the percentage removal of NO gradually decreases, and it can be understood that the amount of decrease in the percentage removal of NO is smaller for the case in which the dielectric material D is not in contact with the first and second electrodes E1 and E2 (Nos. 7 to 12) in comparison with the case in which the dielectric material D is in contact with one of the first and second electrodes E1 and E2 (Nos. 1 to 6). The reason is as mentioned above that placing the dielectric material D so as not to be in contact with the first and second electrodes E1 and E2 increases the number of surfaces of the first and second electrodes E1 and E2 and the dielectric material D, thereby accelerating the activation of the gas by the plasma.

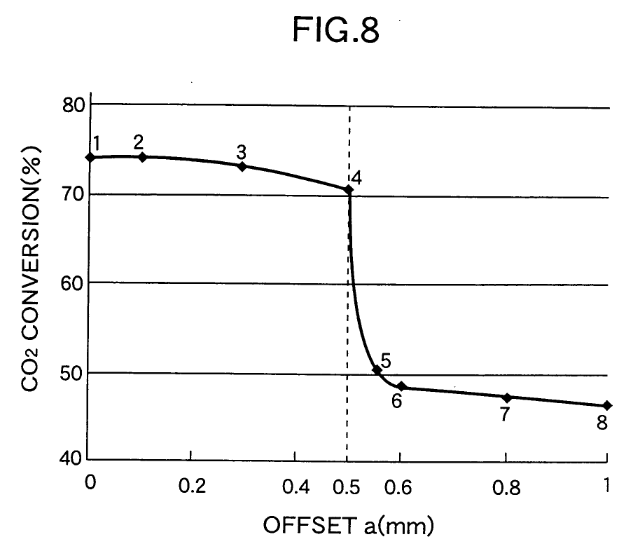

Next, the fifth embodiment is explained by reference to Tables 9 and 10 and FIG. 8.

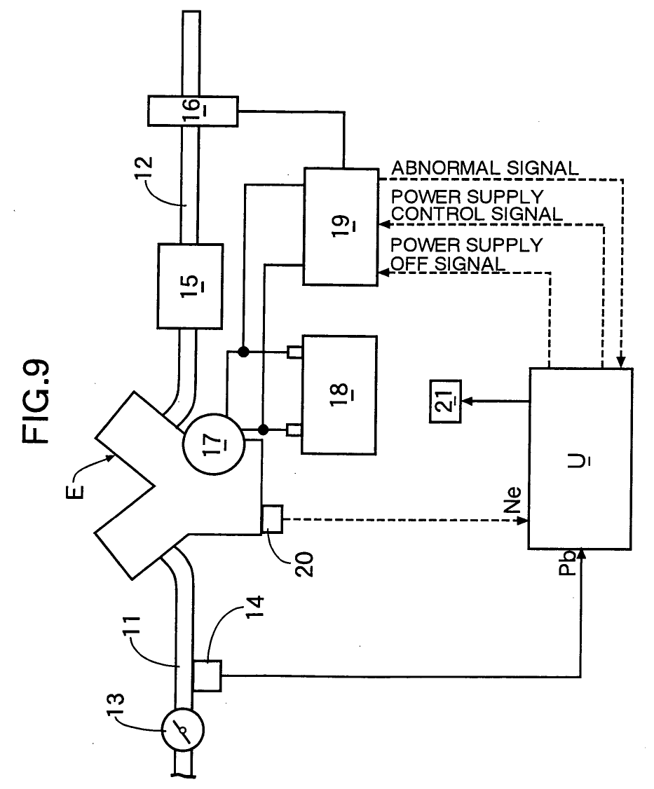

The fifth embodiment which corresponds to the second embodiment verifies the ability of the plasma reactor PR shown in FIG. 6 when applied to the system shown in FIG. 2, to decompose the CO₂ present in the same gas as in the second embodiment. The test conditions are given in Table 9 and the test results are given in Table 10 and FIG. 9.

TABLE 9
Embodiment 5
Test Conditions

| | | Thickness | | | | | | |
|---|---|---|---|---|---|---|---|---|
| | | of | Electrode | | | | Input | Flow |
| | | dielectric | distance; | Offset; | | Frequen- | voltage | rate; |
| | Dielectric | material; t | d | A | | cy; f | Vin | Q |
| No. | material | (mm) | (mm) | (mm) | d/t | (kHz) | (kVp) | (mL/min) |
| 1 | ZrO₂ | 1 | 3 | 0 | 2 | 50 | 4.5 | 1000 |
| 2 | ↑ | ↑ | ↑ | 0.1 | ↑ | ↑ | ↑ | 1000 |
| 3 | ↑ | ↑ | ↑ | 0.3 | ↑ | ↑ | ↑ | 1000 |
| 4 | ↑ | ↑ | ↑ | 0.5 | ↑ | ↑ | ↑ | 1000 |
| 5 | ↑ | ↑ | ↑ | 0.55 | ↑ | ↑ | ↑ | 1000 |
| 6 | ↑ | ↑ | ↑ | 0.6 | ↑ | ↑ | ↑ | 1000 |
| 7 | ↑ | ↑ | ↑ | 0.8 | ↑ | ↑ | 4.3 | 1000 |
| 8 | ↑ | ↑ | ↑ | 1 | ↑ | ↑ | 4.3 | 1000 |

TABLE 10
Embodiment 5
Test Conditions

| | Effective | Average current | CO₂ |
|---|---|---|---|
| | current; lrms | density; lrd | conversion |
| No. | (A) | (A/cm²) | (%) |
| 1 | 8.20 × 10⁻² | 4.10 × 10⁻² | 74.3 |
| 2 | 8.20 × 10⁻² | 4.10 × 10⁻² | 73.9 |
| 3 | 8.20 × 10⁻² | 4.10 × 10⁻² | 73.2 |
| 4 | 8.20 × 10⁻² | 4.10 × 10⁻² | 70.8 |
| 5 | 8.20 × 10⁻² | 4.10 × 10⁻² | 50.1 |
| 6 | 8.20 × 10⁻² | 4.10 × 10⁻² | 48.5 |
| 7 | 7.70 × 10⁻² | 3.85 × 10⁻² | 47.1 |
| 8 | 7.70 × 10⁻² | 3.85 × 10⁻² | 46.3 |

In the present embodiment, the distance da between the first and second electrodes E1 and E2 is fixed at 3 mm, the thickness t of the dielectric material D is fixed at 1 mm, and the conversion of CO₂ is measured by variously changing the offset a of the dielectric material D. When the offset a of the dielectric material D is in the range from 0 mm to 0.5 mm (values which satisfy the formula a≦0.5× (d/2))s in Nos. 1 to 4, high CO₂ conversion is obtained, but when the offset a of the dielectric material D is in the range from 0.55 mm to 1.0 mm (values which do not satisfy the formula a≦0.5×(d/2)) as in Nos. 5 to 8, a very low CO₂ conversion is obtained. The reason is as described above that when the offset a of the dielectric material D increases, the size of one of the first and second gaps G1 and G2 is greatly reduced and the gas cannot pass through the gap smoothly thus reducing the CO₂ conversion.

Next, the sixth embodiment is explained by reference to FIGS. 9 to 12.

As shown in FIG. 9, an automobile engine E comprises an intake passage 11 and an exhaust passage 12. A throttle valve 13 and an intake negative pressure sensor 14 are provided in the intake passage 11, and a ternary catalyst 15 for cleaning up toxic components in the exhaust gas and a plasma reactor 16 for cleaning up the remaining toxic components that have not been cleaned up by the ternary catalyst 15 are provided in the exhaust passage 12. A power supply circuit 19 outputs an alternating voltage having a waveform such as a sine wave, a square wave, a triangular wave, a pulse wave or a combination thereof, the power supply circuit 19 being connected to a battery 18 that is charged by a generator 17 driven by the engine E.

An intake negative pressure Pb detected by the intake negative pressure sensor 14 provided in the intake passage 11 and an engine rotational rate Ne, detected by an engine rotational rate sensor 20, are input into an electronic control unit U. The electronic control unit U controls the commencement and termination of the operation of the plasma reactor 16 based on the intake negative pressure Pb and the engine rotational rate Ne, and determines abnormality based on the voltage V that is applied to the plasma reactor 16. When abnormality is detected, the electronic control unit U outputs a signal for terminating the operation of the plasma reactor 16 to the power supply circuit 19, and notifies the driver by operating warning means 21 such as a lamp, a chime or a buzzer.

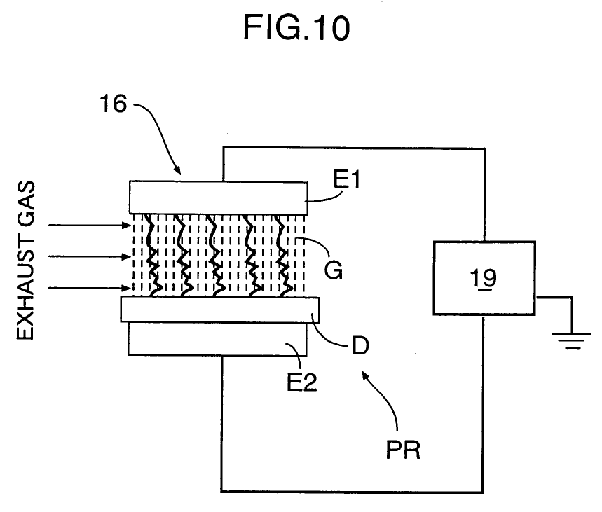

As shown in FIG. 10, the plasma reactor 16 comprises a pair of first and second electrodes E1 and E2, made of metal, placed in parallel to face each other, and a dielectric material D placed to have one surface in contact with the surface of the second electrode E2 facing the first electrode El, and an alternating voltage of, for example, 3000 V and 20 kHz is applied by the power supply circuit 19 to the first and second electrodes E1 and E2. The dielectric material D comprises a material such as, for example, Al₂O₃ (alumina) or ZrO₂ (zirconia). A gap G is formed between the first and second electrodes E1 and E2 through which the exhaust gas passes. By generating a discharge in the gap G between the first electrode E1 and the dielectric material D, the exhaust gas passing through the gap G is activated into a plasma state thus accelerating the chemical reactions of the exhaust gas to convert it into nontoxic materials.

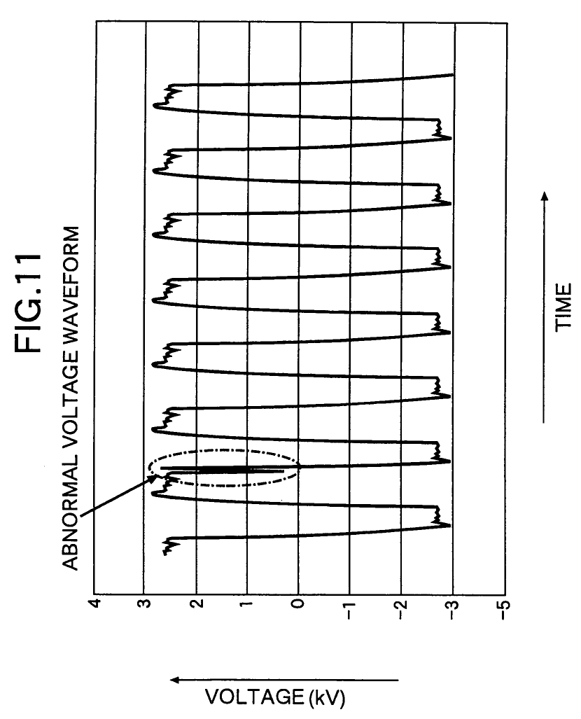

FIG. 11 shows a waveform of the alternating voltage applied to the plasma reactor 16 by the power supply circuit 19. When a deposit, etc. are attached to the surfaces of the first and second electrodes E1 and E2 and the dielectric material D of the plasma reactor 16, the ability to clean up the exhaust gas is degraded, and an abnormal spike-shaped waveform appears in the waveform of the alternating voltage. In the example shown in FIG. 11, an abnormal waveform of about 2500 V is superimposed on an alternating voltage of 3000 V. It is therefore possible to determine abnormality (deterioration or malfunction) in the plasma reactor 16 at an early stage by detecting this abnormal waveform.

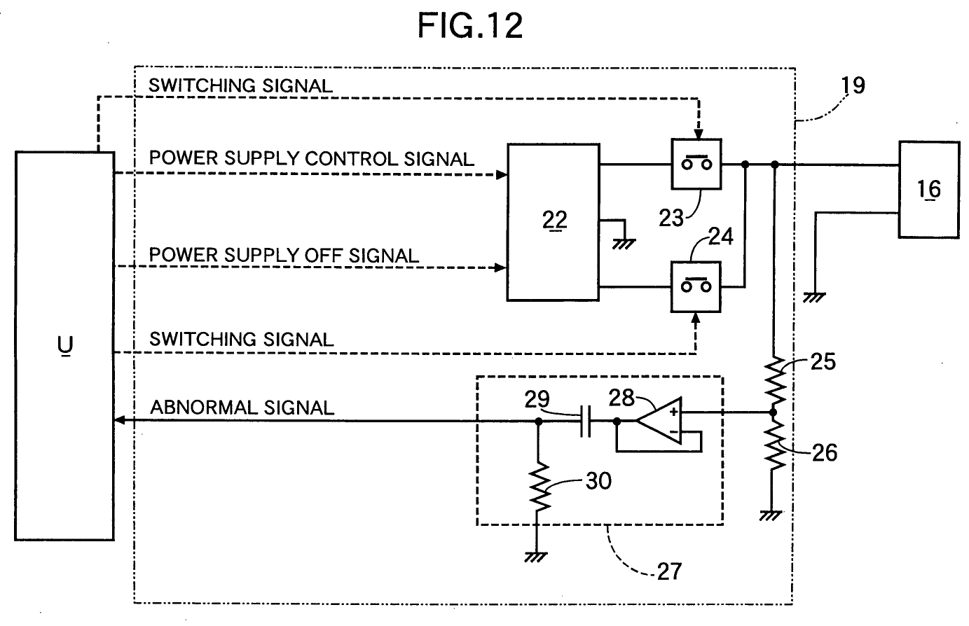

As shown in FIG. 12, the power supply circuit 19 comprises a voltage booster section 22 for boosting the voltage of a battery 18 to +3000 V and −3000 V, and by alternately switching over a pair of switches 23 and 24 placed between a pair of output terminals of the voltage booster section 22 and the plasma reactor 16, based on the switching signal from the electronic control unit U, an alternating voltage having a frequency of, for example, 20 kHz is applied to the plasma reactor 16.

The voltage applied to the plasma reactor 16 is divided by two resistors 25 and 26 and input to a high-pass filter 27. The high-pass filter 27 comprises an operational amplifier 28 for input protection, a capacitor 29 and a resistor 30, and it is set so that only signals having a frequency higher than that of the alternating voltage can pass through. Since the output from the high-pass filter 27 is input to an interrupt terminal of the electronic control unit U, when the electronic control unit U detects a spike-shaped abnormal waveform having a high frequency, abnormality can be determined. After the electronic control unit U has determined abnormality in the plasma reactor 16, the electronic control unit U outputs a power supply OFF signal to the voltage booster section 22 to block the application of the alternating voltage to the plasma reactor 16, and simultaneously operates the warning means 21 to notify the driver of the occurrence of abnormality.

As described above, since abnormality can be determined simply by monitoring the waveform of the alternating voltage applied to the plasma reactor 16, abnormality can be determined even when the engine E is not in operation. Further, since there is no need for a gas sensor which is needed in the art, not only can the cost be reduced, but also abnormality can be determined in real time by eliminating the time lag according to the distance between the plasma reactor 16 and the gas sensor. It is also possible to identify degradation of the plasma reactor 16 at an early stage by detecting a spike-shaped abnormal waveform caused by a deposit, etc. generated on the surface of the electrode E1 or E2 or the dielectric material D, and appropriate maintenance can thus be carried out.

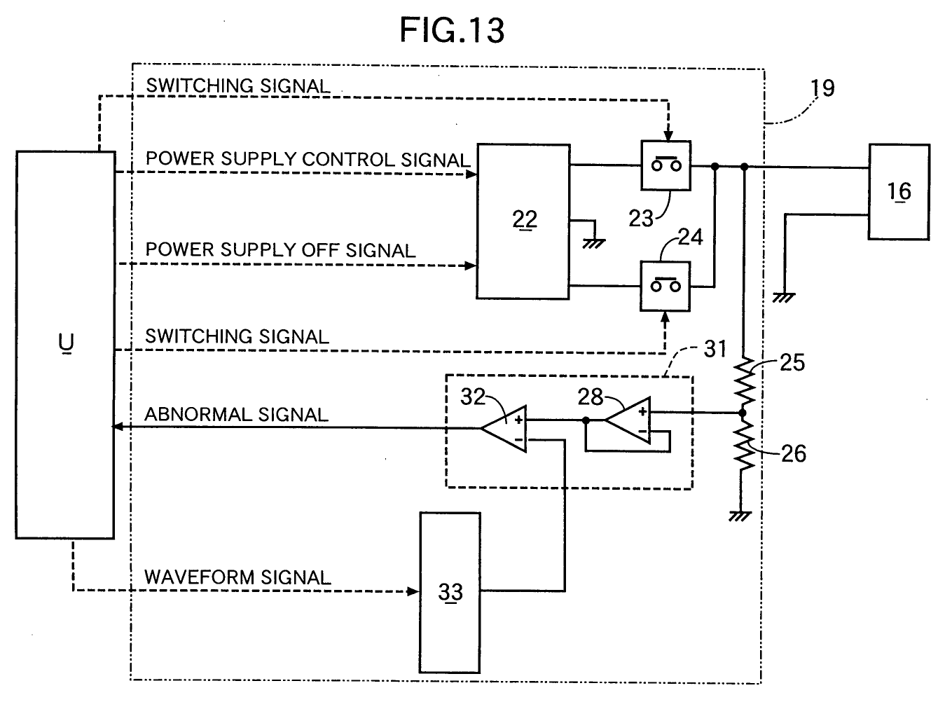

Next, the seventh embodiment of the present invention is explained by reference to FIG. 13.

A power supply circuit 19 of the seventh embodiment comprises a voltage comparator section 31 instead of the high-pass filter 27 of the power supply circuit 19 of the sixth embodiment. The voltage comparator section 31 comprises an operational amplifier 28 for input protection and a comparator 32. The waveform signal of the alternating voltage is input from an electronic control unit U to a digital/analog converter 33, and the output from the digital/analog converter 33 and the output from the operational amplifier 28 are input into the comparator 32, and therein compared with each other. If a spike-shaped abnormal waveform occurs in the waveform of the alternating voltage input to the plasma reactor 16, the signal of the abnormal waveform is therefore input to the electronic control unit U, and abnormality in the plasma reactor 16 is determined.

The same functional effects as in the sixth embodiment can be obtained by the seventh embodiment.

The plasma reactor of the present invention can be also used in desired applications other than the cleanup of an automobile exhaust gas.

Moreover, the dielectric material D can be made from an inorganic oxide or a non-oxide ceramic other than Al₂O₃ (alumina) and ZrO₂ (zirconia), such as SiO₂ (glass), BaTiO₃ (barium titanate) or SiN₄ (silicon nitride), and the same effects can be exhibited by the use of any type of dielectric material D. It is desirable for the electrodes E1 and E2 of the plasma reactor PR to have a width that is sufficient for the target gas passing through them to be reacted.

In the sixth and seventh embodiments abnormality is determined by monitoring the alternating voltage applied to the plasma reactor 16, but the same effects can be achieved by monitoring the alternating current instead of the alternating voltage.

The present invention may be embodied in other specific forms without departing from the spirit or essential characteristics thereof. The presently disclosed embodiments are therefore to be considered in all respects as illustrative and not restrictive, the scope of the invention being indicated by the appended claims, rather than the foregoing description, and all changes which come within the meaning and range of equivalency of the claims are, therefore, to be embraced therein.

1. A method of determining abnormality in a plasma reactor having a pair of facing electrodes, comprising the steps of applying an alternating current to the electrodes for generating a plasma in a gas passing through the gap between the two electrodes to thereby modify the gas and monitoring the voltage or current waveform on the electrode, wherein the determination of abnormality is based on a change in the waveform of the voltage or current of the alternating current.

2. A method of determining abnormality in a plasma reactor according to claim 1, further including the step of filtering the monitored voltage or current with a high-pass filter, wherein abnormality is determined if a spike-shaped abnormal waveform is detected when the waveform of the voltage or current of the alternating current is filtered by the high-pass filter.

3. A method of determining abnormality in a plasma reactor according to claim 1, further including the step of comparing the waveform of the monitored voltage or current with a reference waveform, wherein abnormality is determined if a spike-shaped abnormal waveform is detected when the waveform of the voltage or current of the alternating current is compared with the reference waveform.
